(19) United States
(12) Patent Application Publication
(10) Pub. No.: US 2025/0239462 A1
(43) Pub. Date: Jul. 24, 2025

(54) IMMERSION PLATING PROCESS FOR AN INTEGRATED CIRCUIT

(71) Applicant: TEXAS INSTRUMENTS INCORPORATED, DALLAS, TX (US)

(72) Inventors: NAZILA DADVAND, Santa Clara, CA (US); HUO YUN DUAN, Chengdu (CN); XUAN MO LI, Chengdu (CN)

(21) Appl. No.: 18/416,513

(22) Filed: Jan. 18, 2024

(51) Int. Cl. H01L 21/48; C23C 18/54; H01L 21/56; H01L 23/00; H01L 23/31; H01L 23/495

(52) U.S. Cl. CPC H01L 21/4828; C23C 18/54; H01L 23/49582; H01L 24/32; H01L 24/48; H01L 24/73; H01L 24/92; H01L 21/56; H01L 23/3121; H01L 2224/32245; H01L 2224/48091; H01L 2224/48245; H01L 2224/73265; H01L 2224/92247

(57) ABSTRACT

An electronic device and method thereof are provided where the method includes providing an electronic device having a substrate and a die disposed on the substrate. The electronic device is immersed in a liquid metal ion solution to chemically displace metal ions from exposed surfaces on the substrate, wherein ions from the liquid metal ion solution combine with the displaced metal ions from the substrate to form an immersion plating layer on exposed surfaces of the substrate.

### TECHNICAL FIELD

The present disclosure relates to an electronic device and more specifically, to an integrated circuit package that includes conductive terminals having immersion plated surfaces.

### BACKGROUND

Immersion plating is the process of applying one or more layers of one metal to another metal's surface by immersing the metal in ion solution to produce a replacement or chemical exchange reaction. The chemical exchange reaction causes a deposition of a metallic coating on a base metal from the ion solution. Specifically, one metal is typically displaced by metal ions that have lower levels of oxidation potential, relative to the metal ion being displaced. Immersion plating improves the electrical and bonding properties of the coated metal.

### SUMMARY

In another described example, a method includes providing an electronic device having a substrate and a die disposed on the substrate. The electronic device is immersed in a liquid metal ion solution to chemically displace metal ions from exposed surfaces on the substrate, wherein ions from the liquid metal ion solution combine with the displaced metal ions from the substrate to form an immersion plating layer on exposed surfaces of the substrate.

In still another described example, a method of fabricating an electronic device includes providing a leadframe having a die pad and conductive terminals and placing a die on the die pad via a die attach material. Wire bonds are attached from an active surface of the die to the conductive terminals. A mold compound is formed over the die, where the mold compound covers all but two surfaces of the substrate, where the two surfaces not covered face away from the die and are substantially perpendicular to each other. The electronic device is immersed in a liquid metal ion solution to chemically displace metal ions from exposed surfaces of the conductive terminals. Ions from the liquid metal ion solution combine with the displaced metal ions from the exposed surfaces of the conductive terminals to form an immersion plating layer on exposed surfaces of the substrate.

In described examples, an electronic device includes a substrate having a die pad and conductive terminals, where exposed surfaces of the conductive terminals have an immersion plating layer chemically formed therein. A die that includes an active surface is disposed on the die and wire bonds connect the active surface of the die to the lead terminals. A mold compound encapsulates the die and the wire bonds, where the mold compound covers all but two surfaces of the substrate, where the two surfaces not covered face away from the die and are substantially perpendicular to each other.

### BRIEF DESCRIPTION OF THE DRAWINGS

FIG. 1A is a cross sectional view of an example electronic device.

FIG. 1B is a close-up view of a conductive terminal of the example electronic device of FIG. 1A.

FIG. 2 is a block diagram flow chart illustrating a fabrication process for the electronic device of FIG. 1A.

FIG. 3A is a top view of a wafer that includes dies.

FIG. 3B illustrates a cross sectional view of a singulated die from the wafer in FIG. 3A in the early stages of fabrication of a die assembly.

FIG. 3C illustrates a cross sectional view of a leadframe based substrate in the early stages of assembly of an electronic device.

FIG. 3D illustrates a cross sectional view of the leadframe based substrate of FIG. 3C after deposition of a die attach material.

FIG. 3E illustrates a cross sectional view of the electronic device of FIG. 3D with a die attached to the leadframe.

FIG. 3F illustrates a cross sectional view of the electronic device of FIG. 3E after undergoing a wire bonding process.

FIG. 3G illustrates a cross sectional view of the electronic device of FIG. 3F after undergoing formation of a mold compound.

FIG. 3H illustrates a cross-sectional view of the electronic device of FIG. 3G after undergoing an etch process.

FIG. 3I illustrates a cross-sectional view of the electronic device of FIG. 3H after undergoing an immersion plating process.

### DETAILED DESCRIPTION

Integrated circuit (IC) packages such as a QFN package have exposed surfaces on conductive terminals. Other packages such as DIP or SOIC package include external leads. The exposed surfaces or external leads can be plated with a metallic coating to improve, inter alia, electrical and bonding properties. One such plating method is immersion plating where one or more layers of one metal is applied to another metal's surface by immersing the metal in ion solution to produce a replacement or chemical exchange reaction. The chemical exchange reaction causes a deposition of a metallic coating on a base metal from the ion solution. One metal is typically displaced by metal ions that have lower levels of oxidation potential, relative to the metal ion being displaced. Immersion plating is also utilized to improve electrical properties as well as to enhance organic coatings or adhesive coating's bonding to a substrate. Immersion plating improves, inter alia, electrical properties (e.g., conductivity), wear and corrosion resistance, reflectivity and appearance, chemical resistance and hardness, torque tolerance, and bonding capabilities.

The method of plating one metal with another metal, however, can require several process steps, which increases fabrication costs. Specifically, the process includes deflashing the IC package after applying the mold compound to remove any mold compound resin from the exposed surfaces of conductive terminals. The method further includes a matte plating step to an exposed surface of the conductive terminals or to the external leads. The method further includes an annealing step to make the matte plating pliable. The IC package is mounted to a carrier (e.g., tape), and then singulated. Finally, the IC package undergoes an immersion plating step to apply a metal to the surface of the conductive terminals or the external leads. Disadvantages of this process, however, is that a thickness of the matte plating is approximately 11-13 μm. The thickness of the immersion plating step is approximately another 2-4 μm. Thus, the combined thickness of both the matte plating and the immersion plating is 13-17 μm, which leads to a larger package size and an increase in material costs. In addition, the extra steps of applying the matte plating and annealing leads to higher fabrication costs.

Disclosed herein is an IC fabrication process that overcomes the aforementioned disadvantages. The process eliminates both the matte plating step and the annealing step, which reduces material and fabrication costs. Specifically, after fabrication of the IC package, the method includes deflashing, package mounting, singulation, and immersion plating. The thickness of the immersion plating is approximately 3 μm, which results in a smaller package and reduced material costs.

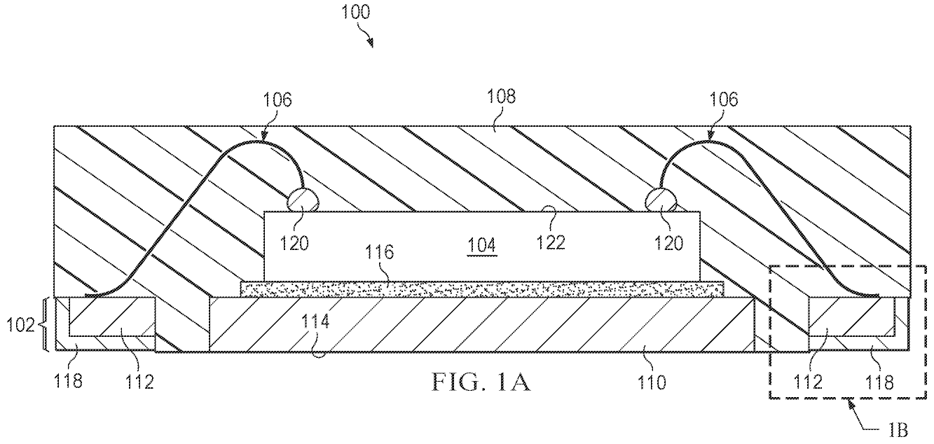

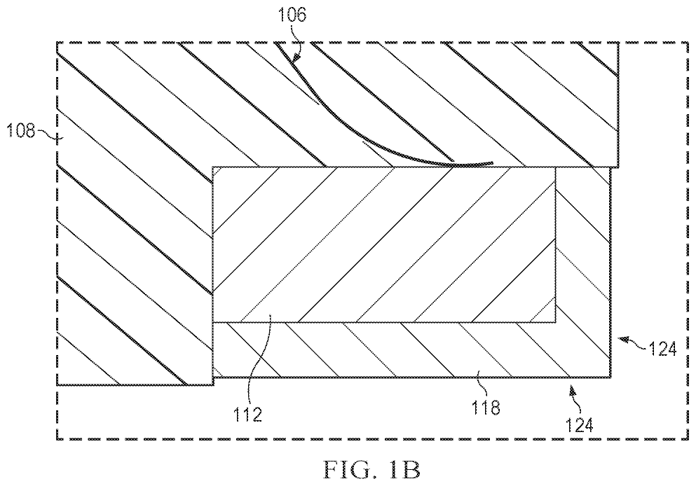

FIG. 1A is a cross sectional view of an example electronic device (e.g., integrated circuit (IC)) 100 and FIG. 1B is a close-up view of a conductive terminal of the example electronic device 100 of FIG. 1A. The electronic device 100 includes a substrate 102, a die 104 disposed on the substrate 102, wire bonds 106, and a mold compound 108. The electronic device 100 can be comprised of a leaded or non-leaded integrated circuit (IC) including, but not limited to a Quad Flat No-Lead (QFN) package, a Quad-Flat Package (QFP), Dual In-Line Package (DIP), Single In-Line Package (SIP), Small Outline Package (SOP), etc. Although, the example electronic device 100 in FIG. 1A is an example illustration of a QFN package, the electronic device 100 illustrated in FIG. 1A is for illustrative purposes only and is not intended to limit the scope of the invention.

The substrate 102 is comprised of a leadframe that includes a die pad 110 and conductive terminals 112 (e.g., leads, contacts). In alternative examples, the substrate may be comprised of a laminate substrate or a printed circuit board based substrate. For illustrative purposes only, a leadframe based substrate will be described herein and illustrated in the drawings. The die pad 110 may be comprised of a thermal pad that is exposed on an attachment side 114 of the electronic device 100. The thermal pad creates an efficient heat path away from the electronic device 100 to a board (e.g., printed circuit board). In addition, the exposed thermal pad or die pad 110 also enables a ground connection to the board. The die 104 attaches to the die pad 110 via a die attach material 116.

Still referring to FIG. 1A and also to FIG. 1B, exposed surfaces, i.e., the surfaces not covered by the mold compound 108, of the conductive terminals 112 include a plated layer 118 (e.g., tin). The plated layer 118 is applied via immersion plating with a liquid metal ion solution. A thickness of the plated layer is approximately 2-4 μm. Prior to the immersion plating process, however, the exposed surfaces of the conductive terminals 112 are etched (explained further below) approximately 5-7 μm to form a recess with respect to the mold compound 108. Thus, since the etched recess is approximately 5-7 μm and the thickness of the plated layer is approximately 2-4 μm, the conductive terminals 112 are recessed 124 inward from the mold compound 108 by approximately 1-5 μm. The plated layer 118 improves, inter alia, electrical properties (e.g., conductivity), wear and corrosion resistance, reflectivity and appearance, chemical resistance and hardness, torque tolerance, and bonding capabilities of the conductive terminals 112.

The wire bonds 106 are connected to the ball bonds 120 and provide a connection between an active surface 122 of the die 104 and the conductive terminals 112. The mold compound 108 encapsulates the die 104, the wire bonds 106, and the ball bonds 120. In the illustrated example, the mold compound 108 covers all but one surface of the substrate 102, where the one surface not covered faces away from the die 104 and the electronic device 100.

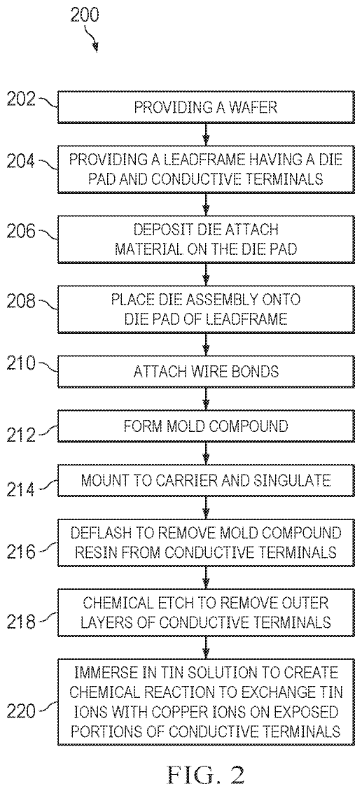

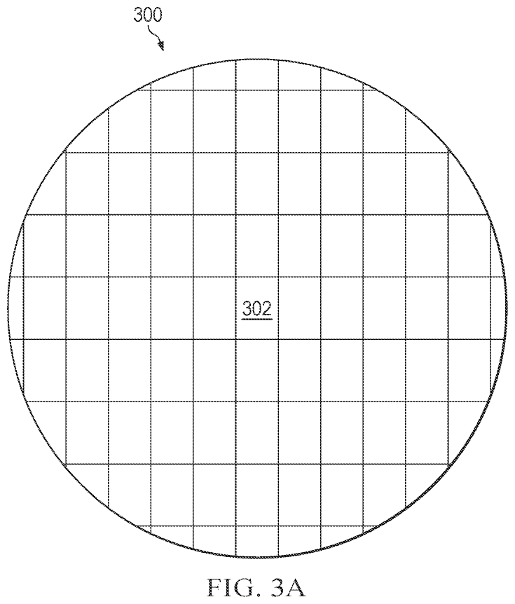

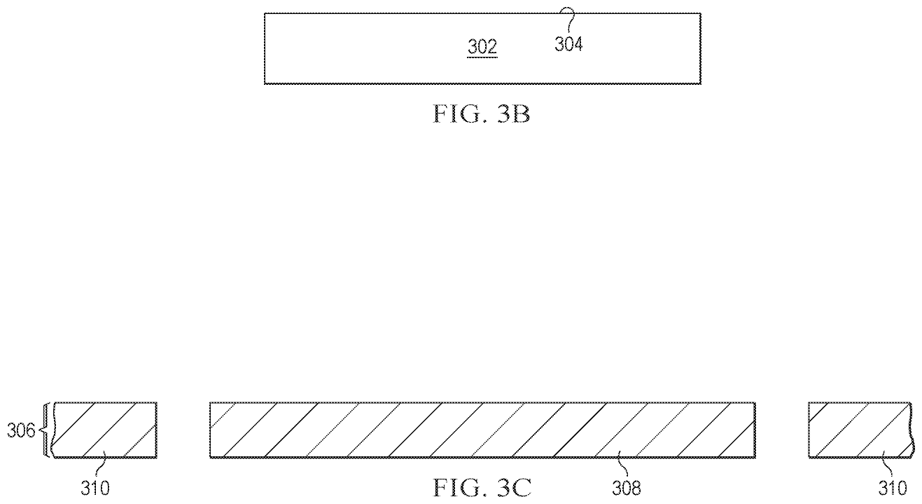

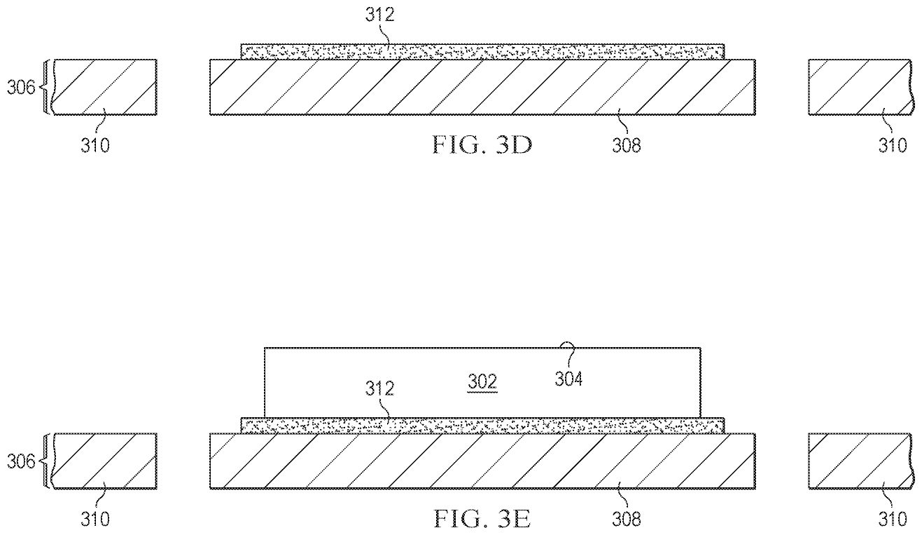

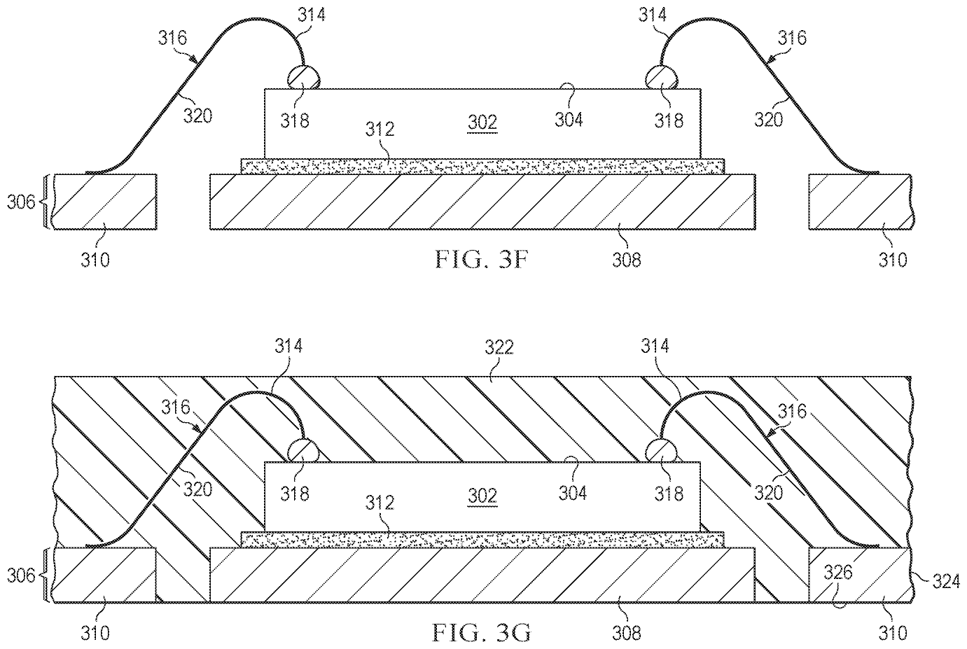

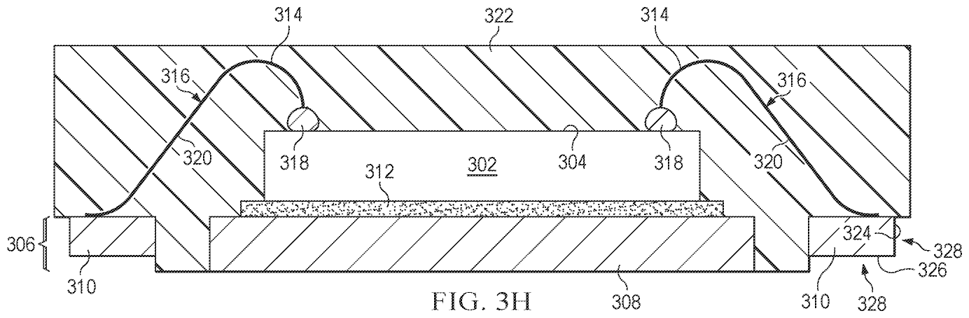

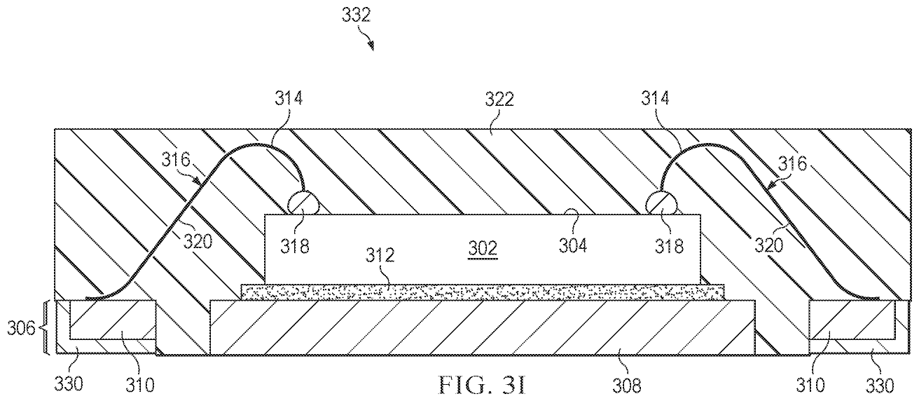

FIG. 2 is a block diagram flow chart explaining a fabrication process 200 and FIGS. 3A-3H illustrate a fabrication process associated with the formation of the electronic device 100 illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 2 and 3A-3H is an example method illustrating the example configuration of FIG. 1A, other methods and configurations are possible. It is understood that although the method illustrated in FIGS. 2 and 3A-3H depicts the fabrication process of a single electronic device, the process applies to an array electronic devices. Thus, after fabrication of the array of electronic devices the array is singulated to separate each electronic device 100 from the array.

Referring to FIG. 2 and to FIGS. 3A-3H, the fabrication process of the electronic device 100 illustrated in FIG. 1A begins at 202 with a wafer 300, as illustrated in FIG. 3A. Specifically, FIG. 3A is a schematic diagram of a wafer 300, in accordance with various examples. For example, the wafer 300 may be a silicon wafer. The wafer 300 comprises multiple dies 302. The manufacturing techniques described below may be performed on individual dies 302 (post-singulation), or the techniques may be more efficiently performed on a mass scale, e.g., simultaneously on multiple dies 302 of the wafer 300 (pre-singulation). For convenience and clarity, the remaining drawings show one die 302, with the understanding that the processes described herein as being performed on the die 302 may also be performed (e.g., sequentially performed, simultaneously performed) on the remaining dies 302 of the wafer 300.

FIG. 3B illustrates a cross sectional view of a single die 302 of the wafer 300 where the die 302 includes an active side 304. Referring to FIG. 3C, at 204, a substrate (leadframe) 306 is provided. It is to be understood that in alternative examples, the substrate may be comprised of a laminate substrate or a printed circuit board based substrate. For illustrative purposes only, a leadframe based substrate will be described herein and illustrated in the drawings. The leadframe 306 includes a die pad 308 and conductive terminals 310.

At 206, a die attach material 312 is deposited on the die pad 308 of the leadframe 306 resulting in the configuration of FIG. 3D. For simplicity the dispensed die attach technique is referenced, however, other die attach techniques such as using a die attach film pre applied to the back of the wafer can also be utilized. At 208, the die 302 is picked and placed on the die pad 308 via the die attach material 312 resulting in the configuration of FIG. 3E. At 210, a first end 314 of wire bonds 316 is attached via a ball bond (e.g., solder ball) 318 to the active surface 304 of the die 302 and a second end 320 of the wire bonds 316 is attached to a surface of each of the conductive terminals 310 resulting in the configuration in FIG. 3F.

At 212, a mold compound 322 is formed over the die 302. Specifically, the mold compound 322 encapsulates the die 302, the wire bonds 316, and the ball bonds 318 resulting in the configuration of FIG. 3G. In the illustrated example, the mold compound 322 covers all but one surface of the die pad 308, where the one surface not covered faces away from the die 302. In addition, the mold compound 322 covers all but two surfaces (side surface and bottom surface, collectively “exposed surfaces”) 324, 326 of the conductive terminals 310. At 214, the electronic device (more specifically, the array of electronic devices) are mounted to a carrier (e.g., tape) and singulated. At 216, the singulated electronic devices undergo a deflashing to remove any resin mold compound 322 from the exposed surfaces 324, 326 of the conductive terminals 310.

At 218, a chemical etch is performed to remove approximately 5-7 μm of a portion of the outer layers of the exposed surfaces 324, 326 of the conductive terminals 310 thereby forming a recess 328 resulting in the configuration of FIG. 3H. At 220, the electronic device is immersed in a liquid metal ion solution (immersion plating), which through a chemical exchange reaction forms a plated layer 330 on the exposed surfaces 324, 326 of the conductive terminals 310 resulting in an electronic device 332 in the configuration of FIG. 3I. Specifically, a layer of the exposed surfaces 324, 326 of the conductive terminals 310 is displaced by the chemical exchange reaction and combines with the liquid metal ion solution. A tin ion solution is one example of a liquid metal ion solution used in the immersion plating process. Thus, in an example where the conductive terminals 310 are made from copper, the chemical exchange reaction takes place according to Equation 1.

2Cu+Sn²→2Cu⁺+Sn (1)

Each copper atom from the layer of copper of the conductive terminals 310 oxidizes and releases an electron to form 2Cu+. In addition, during the chemical exchange reaction, the displaced electrons combine with the tin ion solution to form Sn, which forms on the plated layer 330 on the exposed surfaces 324, 326 of the conductive terminals 310.

As a result of immersing the electrical device into the liquid metal ion solution, a layer of the liquid metal (e.g., tin) is deposited on the conductive terminals 310 to replace the removed layer. During deposition of the tin, the tin selectively reacts with only the copper conductive terminals 310. In other words, the tin will not deposit on any other metal or material on the electronic device. As mentioned above, a thickness of the plated layer 330 is approximately 2-4 μm. Thus, since the etched recess 328 is approximately 5-7 μm the conductive terminals 310 are recessed inward from the mold compound 322 approximately 1-5 μm (see recess 124 in FIG. 1B), which results in a smaller IC package and reduced material thereby reducing material costs. Finally, with the elimination of the matte plating step fabrication costs are reduced.

In alternative examples (not shown) of an electronic device it might be desirable to also plate a bottom surface of the die attach pad 308 to improve its electrical properties (e.g., conductivity), wear and corrosion resistance, reflectivity and appearance, chemical resistance and harness, torque tolerance, and bonding capabilities, especially if it is desired to use the die attach pad 308 as a ground connection and/or to reduce corrosion possibilities. In such examples, the bottom surface of die pad 308 would be etched in a similar manner as the bottom surface of conductive terminals 310 are etched in 218 and illustrated in FIG. 3H. Similarly, the etched bottom surface of die pad 308 would thereafter be plated to have a plated bottom surface in a similar manner as the plated layer 330 on the etched bottom surface of conductive terminals 310 as in 220 and illustrated in FIG. 3I.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. A method comprising:
providing an electronic device having a substrate and a die disposed on the substrate; and
immersing the electronic device in a liquid metal ion solution to chemically displace metal ions from exposed surfaces on the substrate, wherein ions from the liquid metal ion solution combine with the displaced metal ions from the substrate to form an immersion plating layer on exposed surfaces of the substrate.

2. The method of claim 1, wherein the liquid metal ion solution is a tin ion solution.

3. The method of claim 1, wherein the substrate includes a die pad and conductive terminals and wherein the immersion plating layer is formed on exposed surfaces of the conductive terminals.

4. The method of claim 3, wherein the die is disposed on the die pad, the method further comprising attaching wire bonds from an active surface of the die to the conductive terminals.

5. The method of claim 4 further comprising forming a mold compound over the die, the mold compound covering all but two surfaces of the substrate, where the two surfaces not covered face away from the die and are substantially perpendicular to each other.

6. The method of claim 5 further comprising deflashing the electronic device to remove mold compound resin from the exposed surfaces of the conductive terminals.

7. The method of claim 1, wherein the immersion plating layer is comprised of tin.

8. The method of claim 1, wherein a thickness of the immersion plating layer is approximately 2-4 μm.

9. A method of fabricating an electronic device comprising:
providing a leadframe having a die pad and conductive terminals;
placing a die on the die pad via a die attach material;
attaching wire bonds from an active surface of the die to the conductive terminals;
forming a mold compound over the die, the mold compound covering all but two surfaces of the leadframe, where the two surfaces not covered face away from the die and are substantially perpendicular to each other; and
immersing the electronic device in a liquid metal ion solution to chemically displace metal ions from exposed surfaces of the conductive terminals, wherein ions from the liquid metal ion solution combine with the displaced metal ions from the exposed surfaces of the conductive terminals to form an immersion plating layer on exposed surfaces of the leadframe.

10. The method of claim 9, wherein prior to immersing the electronic device in a liquid metal ion solution, the method further comprising singulating the electronic device from an array of electronic devices.

11. The method of claim 10, wherein after singulating the electronic device, the method further comprising deflashing the electronic device to remove mold compound resin from the two surfaces not covered by the mold compound.

12. The method of claim 11, wherein after deflashing the electronic device to remove mold compound resin, the method further comprising performing an etch process to remove outer layers from the two surfaces not covered by the mold compound.

13. The method of claim 10, wherein the liquid metal ion solution is a tin ion solution.

14. The method of claim 10, wherein the immersion plating layer is comprised of tin.

15. The method of claim 10, wherein a thickness of the immersion plating layer has a thickness of approximately 2-4 μm.

16. An electronic device comprising:
a substrate having a die pad and conductive terminals, exposed surfaces of the conductive terminals having an immersion plating layer chemically formed therein;
a die having an active surface, the die being disposed on the die pad;
wire bonds connected to the active surface of the die and the conductive terminals; and
a mold compound encapsulating the die and the wire bonds, the mold compound covering all but two surfaces of the substrate, where the two surfaces not covered face away from the die and are substantially perpendicular to each other.

17. The electronic device of claim 16, wherein the exposed surfaces of the conductive terminals are recessed from a surface of the mold compound.

18. The electronic device of claim 16, wherein the immersion plating layer is an ion exchange with a metal of the conductive terminals.

19. The electronic device of claim 16, wherein the immersion plating layer has a thickness of approximately 2-4 μm.

20. The electronic device of claim 16, wherein the immersion plating layer is comprised of tin.
